(19) United States
(12) Patent Application Publication
(10) Pub. No.: US 2008/0158820 A1
(43) Pub. Date: Jul. 3, 2008

(54) HEAT DISSIPATION DEVICE FOR COMPUTER ADD-ON CARDS

(75) Inventors: XUE-WEN PENG, Shenzhen (CN); RUI-HUA CHEN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/681,734

(22) Filed: Mar. 2, 2007

(30) Foreign Application Priority Data
Dec. 27, 2006 (CN) 200610157995.8

(51) Int. Cl. F28F 13/12; H05K 7/20

(52) U.S. Cl. 361/703; 165/122

(57) ABSTRACT

A heat dissipation device (100) is mounted on a heat-generating device (12) of a graphics card (10) and comprises a heat sink (20), a fan (30), a cover (40) and a heat pipe (50). The heat sink (20) has a base (22) and a plurality of fins (24) on the base (22). The fan (30) is mounted on the base (22) of the heat sink (20) beside the fins (24). The cover (40) covers the heat sink (20) and the fan (30). The heat pipe (50) is embedded in a bottom surface of the base (22) of the heat sink (20) in direct contact with the heat-generating device (12). The heat pipe (50) has a bottom face coplanar with the bottom surface of the base (22). The base (22) and the fins (24) are integrally formed as a monolithic piece by aluminum extrusion.

### BACKGROUND OF THE INVENTION

1. Field of the Invention

The present invention relates to a heat dissipation device for computer add-on cards and particularly a heat dissipation device mounted onto a graphics card for dissipation heat generated by the graphics card.

2. Description of Related Art

In order to enable desktop and other computers to rapidly process graphics and game technology, add-on units, generally referred to as “graphics cards” are often installed in computer devices. Such cards comprise a separate processor, called a GPU (graphics processor unit). The GPU generates a large amount of heat during operation. When the temperature of the GPU exceeds a certain level, the GPU may malfunction, or in the worst case fail outright. For this reason, a heat sink is commonly installed on the GPU to dissipate the heat generated by the GPU and other electronic components adjacent to it into ambient air. Generally, the heat sink comprises a base and a plurality of fins is arranged on the base. The base is attached to the GPU mounted on the graphics card so as to absorb the heat. However, only a part of the base, usually a middle part, contacts the GPU. The heat originating from the GPU is directly absorbed by the middle part of the base and cannot quickly spread to other parts of the base. This results in an overheating of the middle part of the base, while the temperature of the other parts of the base is relatively low. The fins on the other parts of the base away from the middle part are not efficiently used. The efficiency of the heat sink needs to be improved through sufficient use of all of the fins on the base.

Accordingly, what is needed is a heat dissipation device with an enhanced heat dissipation performance.

### SUMMARY OF THE INVENTION

According to an embodiment of the present invention, a heat dissipation device is mounted on a heat-generating device of a graphics card and comprises a heat sink, a fan, a cover and a heat pipe. The heat sink has a base and a plurality of fins on the base. The fan is mounted on the base of the heat sink beside the fins. When the fan is activated, an airflow is generated by the fan to flow through the fins. The cover covers the heat sink and the fan. The heat pipe is embedded in a bottom portion of the heat sink in direct contact with the heat-generating device. The base is made of aluminum. Preferably, the heat sink is formed by aluminum extrusion so that the base and the fins are formed as a monolithic piece.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views. Other advantages and novel features will become more apparent from the following detailed description of preferred embodiment when taken in conjunction with the accompanying drawings, in which:

FIG. 1 is an exploded, isometric view of a heat dissipation device in accordance with a preferred embodiment of the present invention and a back plate for securing the heat dissipation device to a graphics card;

FIG. 2 is an assembled view of FIG. 1;

FIG. 3 is an inverted, partly assembled view of the heat dissipation device of FIG. 1; and

FIG. 4 is an assembled view of FIG. 3.

### DETAILED DESCRIPTION OF THE INVENTION

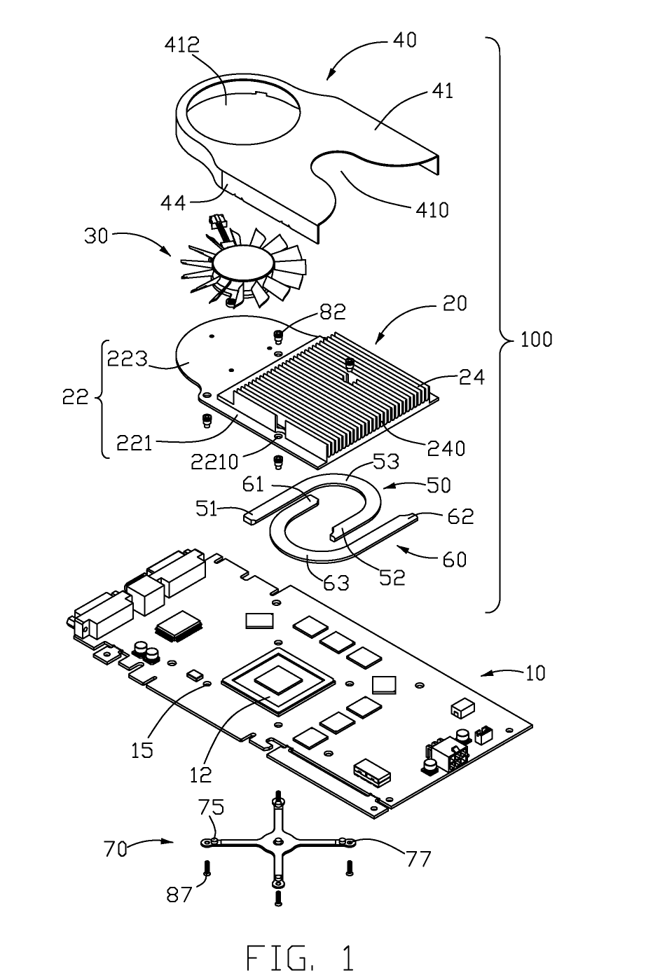

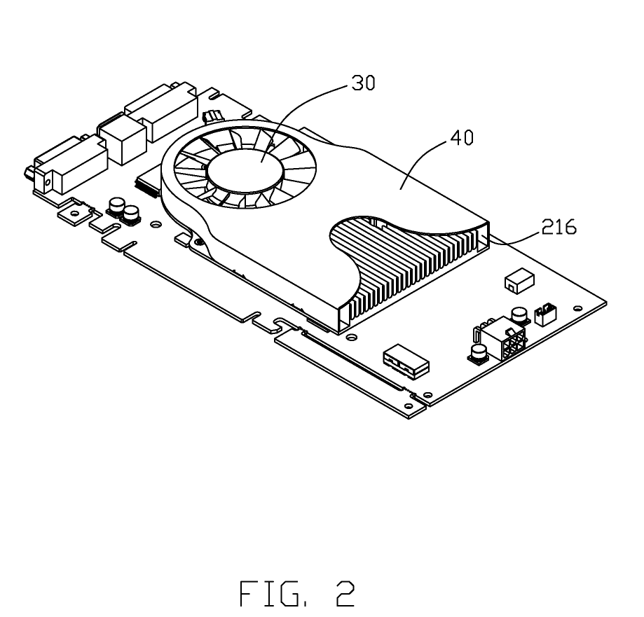

Referring to FIGS. 1-2, a graphics card assembly (not labeled) in accordance with the present invention is illustrated, and comprises a graphics card 10, a heat dissipation device 100 mounted on the graphics card 10 for dissipation of heat generated by a graphic processing unit (GPU) 1 2 of the graphics card 10, and a back plate 70 mounted below the graphics card 10 for securing the heat dissipation device 100 to the graphics card 10.

The heat dissipation device 100 mainly comprises a heat sink 20, a fan 30 mounted on the heat sink 20, a cover 40 covering the heat sink 20 and the fan 30, and first and second heat pipes 50, 60 embedded in a bottom portion of the heat sink 20.

The heat sink 20 is an extruded aluminum-type heat sink. The heat sink 20 comprises a base 22 and a plurality of fins 24 extending from a top surface of the base 22. The base 22 and the fins 24 are formed as a monolithic piece.

The base 22 is a plane plate. The base 22 comprises a rectangular main body 221 and a semicircular extension 223 extending from a front side of the main body 221. The fins 24 are extruded from the main body 221 and extend upwardly therefrom. A portion of the main body 221 of the base 22 where the fins 24 extend is thicker than other portions of the base 22 in such a manner that the first and second heat pipes 50, 60 are embedded in the portion of the main body 221 at a bottom of the base 22. The fins 24 are aligned parallel to each other to form channels 240 therebetween. The main body 221 defines four through holes 2210 therein for providing passages for four fastening members 82. The fastening members 82 form internal threads (not labeled) therein. The fastening members 82 are mounted on the main body 221 for engaging with corresponding screws 87, thus assembling the graphics card 10, the back plate 70 and the heat sink 20 together.

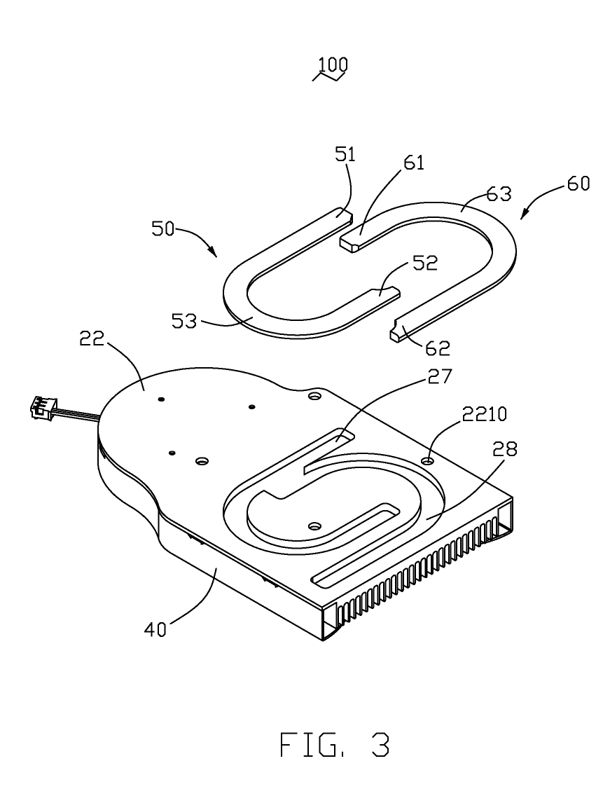

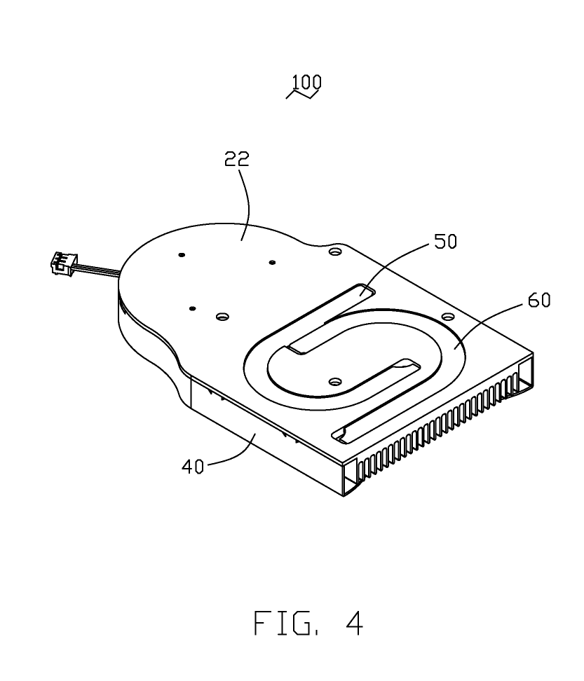

Referring also to FIGS. 3-4, two grooves 27, 28 are defined at the bottom surface of the base 10 to receive the first and second heat pipes 50, 60. The grooves 27, 28 each has a U-shaped configuration and comprises two separate arms (not labeled) which have different lengths, i.e., a longer arm and a shorter arm. The arms of the grooves 27, 28 are parallel to each other and communicate with each other at two neighboring arms via a connecting portion (not labeled). The openings of the grooves 27, 28 are oriented in opposite directions. The shorter arm of the groove 27 is located between the arms of the groove 28 and the shorter arm of the groove 28 is located between the arms of the groove 27, wherein the shorter arm of the groove 28 communicates with the longer arm of the groove 28.

The first and second heat pipes 50, 60 are flattened and U-shaped, corresponding to the grooves 27, 28. The first heat pipe 50 comprises an longer evaporating portion 51 received in the longer arm of the groove 27, a shorter condensing portion 52 received in the shorter arm of the groove 27, and an adiabatic portion 53 received in the connecting portion of the groove 27 to connect the evaporating portion 51 and the condensing portion 52. The second heat pipe 60 comprises a shorter evaporating portion 61 received in the shorter arm of the groove 28, a longer condensing portion 62 received in the longer arm of the groove 28, and an adiabatic portion 63 received in the connecting portion of the groove 28 to connect the evaporating portion 61 and the condensing portion 62. The evaporating portions 51, 61 of the first and second heat pipes 50, 60 are adjacent to each other. However, the heat pipes 50, 60 are not limited to be U-shaped as described in the preferred embodiment, other shaped heat pipes such as V-shaped, C-shaped, or L-shaped heat pipes are also feasible to be used in the heat sink 20.

The cover 40 comprises a top wall 41 spaced from the base 22 and a sidewall 44 extending downwardly from an edge of the top wall 41. The top wall 41 defines a circular intake 412 therein in alignment with the fan 30. An outlet 216 is formed between the cover 40 and the base 22. The outlet 216 is perpendicular to the intake 412 and remote from the intake 412. An arced opening 410 is defined in the top wall 41 and communicates with the outlet 216 for increasing the area of the outlet 216.

The fan 30 is a centrifugal fan. The fan 30 is located on the extension 223 of the base 22, beside the fins 24 and adjacent to channels 240 of the fins 24.

The back plate 70 is attached to a bottom side of the graphics card 10 opposite to the heat dissipation device 100. The back plate 70 is cross-shaped and defines four through holes 77 therein. Five partition gaskets 75 are fixed between the graphics card 10 and the back plate 70 to prevent a physical contact between the back plate 70 and the graphics card 10 so that the back plate 70 is electrically insulated from the graphic card 10.

Referring to FIG. 1 and FIG. 4 again, the heat pipes 50, 60 are fixed in the grooves 27, 28 by soldering or with adhesive to form a flat bottom surface together with the base 22 in direct contact with the top surface of the GPU 12 of the graphics card 10. The openings of the first and second heat pipes 50, 60 are oriented in opposing directions. The heat pipes 50, 60 are so arranged that the condensing portion 52 of the heat pipe 50 extends into space defined by the U-shaped heat pipe 60 and the evaporating portion 61 of the heat pipe 60 extends into space defined by the U-shaped heat pipe 50. The evaporating portion 61 of the heat pipe 60 is adjacent to the evaporating portion 51 of the heat pipe 50. The fan 30 is mounted on the base 22. The screws 87 are then extended through the through holes 77 of the backboard 70 and the through holes 1 5 of the graphics card 10 and threadedly engaged in the fastening members 82. Finally, the cover 40 is assembled to cover the heat sink 20 and the fan 30.

In operation of the heat dissipation device, the GPU 12 generates heat. The heat is conducted to the central portion of the base 22 and the evaporating portion 51, 61 of the heat pipes 50, 60 and then is transferred to other parts of the base 22 via the condensing portions 52, 62. So the heat is quickly and evenly spread to the whole base 22. Finally the heat is conducted to the fins 24 from the base 22, to be dissipated to surrounding air by the fins 24 and the airflow generated by the fan 30 and flowing from the intake 412 through the fins 24 to the outlet 216. Thus the heat generated by the GPU 12 is removed quickly.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device mounted on a heat-generating device of a graphics card, comprising:
a heat sink having a base;
a fan mounted on the base of the heat sink;
a cover covering the heat sink and the fan; and
a heat pipe embedded in a bottom portion of the heat sink in direct contact with the heat-generating device.

2. The heat dissipation device as described in claim 1, wherein the heat pipe comprises an evaporating portion in direct contact with the heat-generating device and a condensing portion remote from the heat-generating device.

3. The heat dissipation device as described in claim 2, wherein the heat pipe is flattened and U-shaped.

4. The heat dissipation device as described in claim 3, wherein an additional heat pipe is embedded in the bottom portion of the heat sink and comprises an evaporating portion extending into space defined by the heat pipe and a condensing portion remote from the heat-generating device.

5. The heat dissipation device as described in claim 4, wherein the evaporating portion of the additional heat pipe is adjacent to the evaporating portion of the heat pipe.

6. The heat dissipation device as described in claim 1, wherein a plurality of fins extends from a top surface of the base and forms channels therebetween, the fan being located beside the fins.

7. The heat dissipation device as described in claim 1, wherein the cover comprises a top wall spaced from the base and a sidewall extending downwardly from an edge of the top wall, and an intake is defined in the top wall in alignment with the fan.

8. The heat dissipation device as described in claim 7, wherein an outlet is formed between the cover and the base, perpendicular to the intake and remote from the intake.

9. The heat dissipation device as described in claim 8, wherein an arced opening is defined in the top wall and communicates with the outlet for increasing the area of the outlet.

10. The heat dissipation device as described in claim 6, wherein the fan is located adjacent to channels of the fins.

11. The heat dissipation device as described in claim 1, wherein a back plate is mounted below the graphics card for securing the heat dissipation device to the graphics card.

12. The heat dissipation device as described in claim 1, wherein the heat sink is an extruded aluminum-type heat sink.

13. The heat dissipation device as described in claim 1, wherein the heat pipe is assembled in the bottom of the base to form a flat bottom surface together with the base for contacting with the heat-generating device.

14. An electronic assembly comprising:
a graphic card having a graphic processing unit thereon;
a heat dissipation device mounted on a first surface of the graphic card and thermally connecting with the graphic processing unit;
a back plate mounted on a second surface of the graphic card opposite the first surface;
a plurality of fasteners extending through the heat dissipation device, the graphic card to connect with the back plate so that the graphic card, the heat dissipation device and the back plate are connected together;
wherein the heat dissipation device has an aluminum-made base having a bottom surface and a top surface, a heat pipe embedded in the bottom surface and having a bottom face coplanar with the bottom surface of the heat pipe and contacting with the graphic processing unit, a plurality of fins extending upwardly from the top surface of the base, a fan mounted on the base and located beside the fins, an airflow generated by the fan flowing laterally through the fins, and a cover covering the fins and the fan.

15. The electronic assembly as described in claim 14, wherein the fins and the base are formed as a monolithic piece.

16. The electronic assembly as described in claim 15, wherein the fins and the base are integrally formed as a monolithic piece by aluminum extrusion.

17. The electronic assembly as described in claim 16, wherein the cover has a top wall defining an intake in alignment with the fan and an outlet with an end of the base distant from the intake, the cover further defining an arced opening above the fins and communicating with the outlet.
